(19) United States
(12) Patent Application Publication
(10) Pub. No.: US 2007/0267683 A1
(43) Pub. Date: Nov. 22, 2007

(54) Nonvolatile memory cell of a circuit integrated in a semiconductor chip, method for producing the same, and application of a nonvolatile memory cell

(75) Inventor: Franz Dietz, Untereisesheim (DE)

Correspondence Address: MCGRATH, GEISSLER, OLDS & RICHARDSON, PLLC, P.O. BOX 1364, FAIRFAX, VA, 22038-1364, US

(73) Assignee: ATMEL GERMANY GmbH

(21) Appl. No.: 11/802,405

(22) Filed: May 22, 2007

Related U.S. Application Data
(60) Provisional application No. 60/802,113, filed on May 22, 2006.

(30) Foreign Application Priority Data
May 22, 2006 (DE) DE10 2006 024 121

(51) Int. Cl. H01L 29/788

(52) U.S. Cl. 257/315

(57) ABSTRACT

A method for producing a nonvolatile memory cell in a semiconductor chip is provided, wherein a gate electrode is produced, a read region is produced, which together with the gate electrode forms a transistor arrangement, a first programming region is produced, which together with the gate electrode forms a first capacitor, a second programming region is produced, which together with the gate electrode forms a second capacitor, and a dielectric insulator is produced, which insulates the gate electrode from the read region and from the first programming region and from the second programming region. The gate electrode is deposited as a conductive layer on the dielectric insulator over the read region and also over the first programming region, as well as over the second programming region.

This nonprovisional application claims priority to German Patent Application No. DE 102006024121, which was filed in Germany on May 22, 2006, and to U.S. Provisional Application No. 60/802,113, which was filed on May 22, 2006, and which are both herein incorporated by reference.

### BACKGROUND OF THE INVENTION

1. Field of the Invention

The present invention relates to a nonvolatile memory cell of a circuit integrated in a semiconductor chip, a method for producing a nonvolatile memory cell in an integrated circuit, and an application of a nonvolatile memory cell in a smart power circuit.

2. Description of the Background Art

In producing integrated circuits, wafers are used which include a monocrystalline semiconductor material such as silicon or germanium, or of mixed crystals such as silicon carbide. Depending on the application, different components, such as CMOS field-effect transistors, bipolar transistors, DMOS field-effect transistors or memory cells, are used in the circuits, placing different demands on a production technology.

It is advantageous to produce a large number of components in one and the same circuit with one production technology. At the same time, the number of process steps in the technology should be kept as small as possible.

One component that is frequently needed is a nonvolatile memory cell of an EPROM or E²PROM memory matrix. The structure and operation of such memory cells can be found in the standard literature. Such memory cells, such as, e.g., dynamic or nonvolatile memory cells, are typically designed such that a charge is introduced into a storage medium of the memory cell during a programming step, and this charge represents the stored information. The information can then be queried in a reading step and, if applicable, can be erased in an erase step.

For these processes, the memory cell uses a programming and erase region as an access region through which the corresponding processes can be carried out. Thus, for example, in the case of an EPROM as a memory transistor, a voltage is applied to the drain and gate of the EPROM for programming, and the charge here flows through a tunnel oxide between the drain and gate as a tunneling current. In the read process, the memory transistor is switched on by application of appropriate voltages or currents to source, gate and drain.

According to U.S. Pat. No. 5,886,376, the programming and erase region of memory cells can be structured as a design unit that can be used for both purposes, wherein some additional adaptations for the function as a programming or read region, such as additional contacting options, tunneling regions for charge carriers, or the like, must be made. With such a combination of these two regions in one design unit, compromise solutions in the optimization are always required, and an inaccuracy, e.g. in the production of a tunneling window in an EPROM, can impair the functionality of the EPROM as a transistor for read operations.

U.S. Pat. No. 5,565,371 discloses a separate design arrangement of the programming region and read region of the memory cell. In this way, separate optimization of the properties of these two regions can be performed with regard to the functions they are to perform, thus improving the effectiveness of the memory cell.

A memory cell with separated programming and read regions is also known from DE 198 46 211 A1. As a result of the insertion of a region that is located below the tunneling window and has doping of the same conductivity type as the source and drain regions of a MOS field-effect transistor of the read region, and also as a result of separate contacting of each of the three regions, an electrical separation of these three regions is achieved in addition to a design separation.

A read operation has practically no effect on a programming operation, and vice versa. Located above the floating gate is a continuous control gate that extends over both the read region and the programming region. Memory cells are typically provided with a separate selection transistor that is used to drive the memory cells. However, in certain operating regions, a selection transistor can be eliminated.

### SUMMARY OF THE INVENTION

It is therefore an object of the present invention to provide a nonvolatile memory cell that has the highest possible cycle lifetime with the simplest design for integration into a circuit having power transistors.

Accordingly, a nonvolatile memory cell of a circuit integrated in a semiconductor chip is provided. This nonvolatile memory cell has a read region for reading out stored information. In addition, the memory cell has a first programming region and a second programming region, wherein preferably a voltage can be applied to the first programming region and to the second programming region for writing and advantageously also for erasing the memory cell.

In addition, the nonvolatile memory cell has a gate electrode, which is designed as a floating gate. To this end, the gate electrode is preferably completely surrounded by a dielectric, and is insulated by it in read mode. The gate electrode has no terminal for this reason. The gate electrode is insulated from the read region, from the first programming region, and from the second programming region by a dielectric insulator.

The gate electrode, together with the dielectric insulator and the read region, forms a transistor arrangement for reading out stored data. To this end, a current can be driven in the transistor arrangement by means of a current source, for example. Depending on the charge in the gate electrode, a drain-source voltage drops across the transistor arrangement, which is turned on or off to a greater or lesser extent, wherein the drain-source voltage is associated with the stored information.

The gate electrode, together with the dielectric insulator and the first programming region, forms a first capacitor. In addition, the gate electrode, together with the dielectric insulator and the second programming region, forms a second capacitor. If a write voltage or an erase voltage is applied to the first and second programming regions, the first capacitor and the second capacitor form a capacitive voltage divider.

With respect to the surface of the semiconductor chip, the gate electrode is located above the read region and above the first programming region and above the second programming region. To this end the gate electrode covers at least a part of the read region, a part of the first programming region, and a part of the second programming region. The dielectric insulator here is located between the gate electrode and the first programming region, between the gate electrode and the second programming region, and between the gate electrode and the read region. Preferably, this part of the dielectric insulator between the gate electrode and the first programming region, between the gate electrode and the second programming region, and between the gate electrode and the read region is formed by a dry thermal oxide of silicon dioxide.

According to an embodiment, provision is made for the first programming region to be insulated from the second programming region by the dielectric insulator. For the purpose of this insulation, preferably a trench structure is provided between the first programming region and the second programming region, which trench structure is filled with a dielectric of the insulator. Advantageously, neither the first programming region nor the second programming region have a pn junction for insulation.

According to another embodiment of the invention, the dielectric insulator additionally has a buried layer (SOI structure (silicon on insulator) or SOS structure (silicon on sapphire)), which is formed below both the first and second programming regions, and advantageously electrically insulates the first and second programming regions from a substrate. Preferably, provision is made for the trench structure to border on the buried layer.

In addition, provision is preferably made for the first programming region and the second programming region to be insulated from the read region by the dielectric insulator. This insulation, too, is advantageously composed of a trench structure that is filled with dielectric. This trench structure, too, advantageously borders on the buried layer. Advantageously, therefore, the first programming region and/or the second programming region and/or the read region are insulated from the substrate of the semiconductor chip by a buried layer (SOI) of the dielectric insulator.

According to a further embodiment of the invention, provision is made for the first programming region and the second programming region and the read region to be made from a single semiconductor layer and to be insulated from one another by a trench structure filled with the dielectric insulator. Preferably, this semiconductor layer has silicon or silicon carbide. This single semiconductor layer is preferably monocrystalline in the first programming region, in the second programming region, and in the read region.

Advantageously, the first programming region is encapsulated by the dielectric insulator so that the first programming region borders on the dielectric insulator on all sides with the exception of an opening for an electrical terminal. To this end, the opening is provided with a metallic conductor, for example. Advantageously, the second programming region is encapsulated by the dielectric insulator so that the second programming region borders on the dielectric insulator on all sides with the exception of an opening for an electrical terminal. TQ this end, the opening is provided with a metallic conductor, for example. Advantageously, the read region is encapsulated by the dielectric insulator so that the read region borders on the dielectric insulator on all sides with the exception of an opening for an electrical terminal. To this end, the opening is provided with a metallic conductor, for example.

Preferably, a first capacitance of the first capacitor and a second capacitance of the second capacitor are different. The ratio of the capacitances here is designed such that a (storage or erase) voltage drops across the first capacitor, permitting tunneling of charge carriers through the dielectric insulator in order to change the stored information. When the first and second capacitors are designed as parallel-plate capacitors, the capacitances are determined by a capacitor area as overlap area of the plates of each capacitor, by the thickness of the dielectric insulator between the plates of each capacitor, and by the material of the dielectric.

Advantageously, provision is made for a first capacitor area of the first capacitor and a second capacitor area of the second capacitor to be different. Advantageously, either alternatively or in combination, the dielectric insulator has a first thickness between the gate electrode and the first programming region, and a second thickness between the gate electrode and the second programming region, these thicknesses being different. The first thickness here is advantageously adapted for tunneling of the charge carriers through this thickness of the dielectric insulator.

In order to simplify a production process as much as possible, the dielectric insulator has the same thickness (within the scope of production tolerances) between the gate electrode and the first programming region and between the gate electrode and the second programming region. This can be achieved by the means that the dielectric insulator is formed on the first programming region and on the second programming region at the same time in one process step.

In addition, the object of the invention is to provide a method for producing a nonvolatile memory cell.

Accordingly, a method for producing a nonvolatile memory cell of a circuit on a semiconductor chip is provided. In this method, a gate electrode, a read region, a first programming region, a second programming region, and a dielectric insulator are formed. The read region forms a transistor arrangement together with the gate electrode and the dielectric insulator. The first programming region forms a first capacitor together with the gate electrode and the dielectric insulator. The second programming region forms a second capacitor together with the gate electrode and the dielectric insulator. The dielectric insulator here is designed such that it insulates the gate electrode from the read region and from the first and second programming regions.

The gate electrode is deposited as a conductive layer on the dielectric insulator over the read region and also over the first programming region and also over the second programming region. For this purpose, a doped polycrystalline semiconductor material is preferably deposited in a single process step and is structured in a later process step, for example by masking and etching.

According to an embodiment, the dielectric insulator is formed by simultaneous thermal oxidation of semiconductor material of the read region, first programming region, and second programming region prior to the deposition of the gate electrode. To achieve different oxide thicknesses on the first programming region and the second programming region, the first programming region is, for example, covered by a Si₃N₄ mask layer following (simultaneous) thermal oxidation of the first programming region, and the oxidation is continued. Alternatively, following the (simultaneous) thermal oxidation, the thermally formed oxide layer can be removed from the first programming region. In a subsequent thermal oxidation, the oxide thickness above the second programming region is made greater than the oxide thickness above the first programming region.

In another embodiment of the method, which is also combinable, the first programming region with the gate electrode and the dielectric insulator is designed as a tunneling window. To this end, at least one dopant with a first dopant concentration of one conductivity type is introduced into the first programming region independently of a dopant concentration of the same conductivity type in the read region. For independent introduction, masking can be used or a doped region is removed by etching, for example.

Another aspect of the invention is an application of an above-described nonvolatile memory cell in an integrated circuit with a number of integrated power transistors as an intelligent power circuit (smart power). A number of nonvolatile memory cells is advantageously produced together with a number of power transistors and other components, wherein individual process steps are used in a synergistic manner both to produce the nonvolatile memory cell and to produce the power transistor.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a schematic three-dimensional layout view of a nonvolatile memory cell; and

FIG. 2 illustrates a schematic circuit symbol of the nonvolatile memory cell.

### DETAILED DESCRIPTION

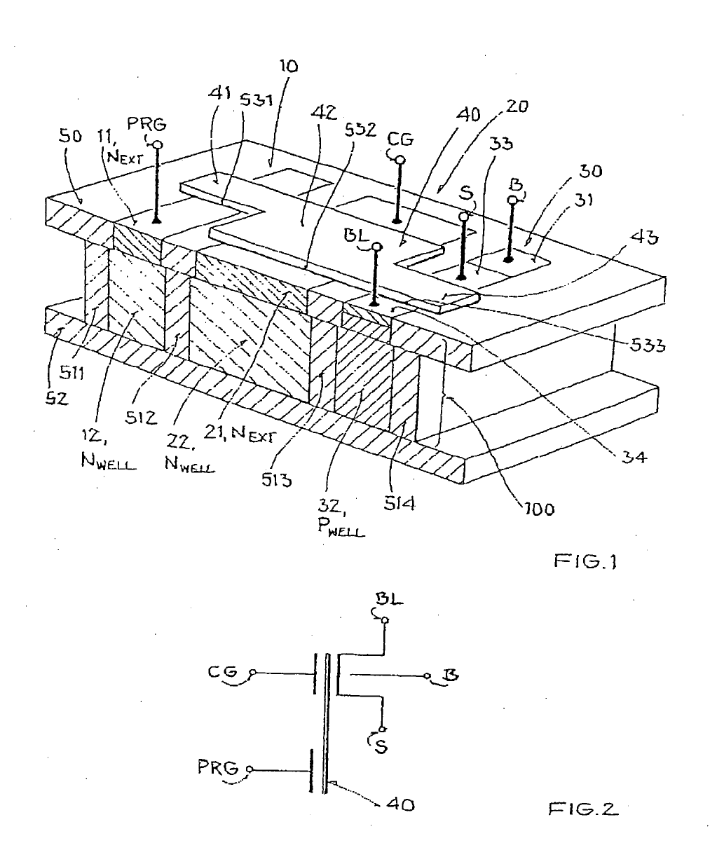

FIG. 1 shows an exemplary embodiment of the invention in a schematic three-dimensional view of a nonvolatile memory cell. A read region 30 is created with a body 32, a body terminal region 31, a source region 33, and a drain region 34 with a terminal BL for a bit line to read out stored information. An NMOS transistor arrangement formed of the source region 33, drain region 34, and body region 32 also has a floating gate electrode 40 above a gate oxide 533. The gate electrode is dielectrically insulated on all sides and can be programmed or erased by tunneling of electrons through the insulation.

In addition to the part 43 of the gate electrode 40, which is a constituent of the transistor arrangement, the gate electrode also has two other parts 41 and 42 that are located above a first programming region 10 and above a second programming region 20. Since all programming regions 10, 20 are located below the gate electrode, an additional programming region above the gate electrode 40 is not necessary, so no second polysilicon layer is necessary on top (no double polysilicon). Only the first programming region 10, second programming region 20, body region 31, source region 33 and drain region 34 have metallic terminals PRG, CG, B, S, BL, respectively. The first programming region 10, second programming region 20, and read region 30 are formed in a monocrystalline semiconductor layer 100 here.

In order to insulate the first programming region 10, second programming region 20, and read region 30 from one another and from the gate electrode 40, a dielectric insulator 50 is provided, which has multiple parts 52, 511, 512, 513, 514, 531, 532 and 533. These parts can be produced in different process steps, and can even have different dielectric materials. As a result of this insulation 50 of the programming regions 10 and 20, a positive as well as negative programming/erase voltage can be applied, independently of a voltage applied to a substrate (not shown in FIG. 1). The geometric area of the second programming region 20 here is significantly larger than the geometric area of the first programming region 10, so that the first parallel plate capacitor formed between gate electrode 40 and the first programming region 10 also has a smaller capacitance than the second parallel plate capacitor formed between gate electrode 40 and the second programming region 20.

The thermal oxide of the dielectric insulator 532 corresponding to the larger second programming region 20 has the advantage that a higher quality of the oxide 532 is achieved in the production. This results in improved charge retention. According to an investigation by the applicant, the possible field strengths for the oxide 532 that is formed on monocrystalline silicon are approximately twice as high as on polycrystalline silicon, which is to say that it would be necessary to double the oxide thickness for polycrystalline material in order to achieve equivalent charge-retaining electrical properties of the oxide 532. As a result, the required capacitance is cut in half as compared to polycrystalline material, or in other words with polycrystalline silicon the capacitance would have to be doubled by means of a larger area for the same electrical properties.

Furthermore, the exemplary embodiment in FIG. 1 has multiple advantages. The tunneling of the electrons can take place through the gate oxide, which is produced in a standard gate oxide process step, wherein the gate oxide for a number of different transistor arrangements, such as CMOS transistors or DMOS transistors, can also be produced at the same time. The read transistor is not subjected to any stress due to the tunneling of the charge carriers in the write or erase process. No significant leakage currents flow within the cell during the write process, even at temperatures of 200° C., so the required programming current is low. The cell is therefore suitable for high temperature use, in particular.

Moreover, simplified driving of the cell from FIG. 1 can be realized in which a drive circuit (not shown) requires a smaller chip area. The cell and its electrical properties do not depend on the tolerances of the lithography. All that is required is a low and symmetrical write/erase voltage. The nonvolatile memory cell degrades symmetrically as a result of write/erase processes and has an adequate cycle lifetime.

FIG. 2 shows a circuit symbol for the memory cell from FIG. 1. Here, the programming terminals CG and PRG, like the terminals S, B and BL of the NMOS transistor arrangement of the read region 30, are insulated from the floating gate electrode 40. A programming voltage is applied between the terminals CG and PRG in order to write the information into the nonvolatile memory cell. The information in the nonvolatile memory cell is erased by means of an erase voltage between the terminals CG and PRG. In contrast, the transistor arrangement is not stressed for erasing or writing, in that an intermediate voltage (with respect to the voltages at the terminals CG and PRG) is applied to the drain and/or source.

The manufacturing process is explained below on the basis of FIG. 1; to facilitate understanding, not all necessary process steps are described, such as lithography steps, cleaning steps, and the like.

First, what is known as an SOI substrate is formed in that a structure having a substrate (not shown in FIG. 1), a monocrystalline semiconductor layer 100, and a dielectric layer 52 buried between the substrate and the monocrystalline semiconductor layer 100 is produced. The dopant of the N conductivity type is introduced to form the N well 12 of the first programming region 10 and to form the N well 22 of the second programming region 20, for example through diffusion. Likewise, the dopant of the P conductivity type, which forms the body 32 of the transistor arrangement here, is introduced into the read region 30.

The body 32 and the two wells 12 and 22 are separated by etching the trench structure with multiple trenches (deep trench). The trenches are then filled with a trench dielectric 511, 512, 513 and 514. The trench dielectric 511, 512, 513 and 514 here reaches to the buried dielectric layer 52. In this context, the trench structure encapsulates the first programming region 10, the second programming region 20, and the read region 30 in the lateral direction (box). These semiconductor regions 10, 20, 30 are thus surrounded in the lateral direction by the trench dielectrics 511, 512, 513 and 514 of the dielectric insulator 50.

After the formation of this lateral insulation, an additional dopant is introduced (for example by implantation) into the top part 11, 21 of the first and second programming regions 10 and 20, so that the dopant concentration NEXT there both reduces the specific resistance and improves cycle lifetime. The P body terminal 31 of the P conductivity type can also be implanted.

The surface of the semiconductor layer 100 of silicon is then dry thermally oxidized, so that a thin silicon oxide layer 531, 532, 533 is formed on the first programming region 10 and on the second programming region 20, and on the read region 30. The first programming region 10, the second programming region 20, and the read region 30 are accordingly surrounded on all sides by a dielectric. The thin silicon dioxide layer has three regions 531, 532, 533 above the first programming region 10, the second programming region 20, and the read region 30, respectively. These regions 531, 532, 533 can have different thicknesses. However, in the example embodiment in FIG. 1, the regions 531, 532, 533 are produced by the same thermal oxidation step and have the same thickness.

Next, doped polysilicon is deposited on the silicon dioxide layer 531, 532, 533 and is structured so as to form the continuous gate electrode 43 with a first part 41 above the first programming region 10, a second part 42 above the second programming region 20, and a third part 43 above the read region 30. The gate electrode 40 is then insulated on all sides by a dielectric and is not contacted, so that a floating gate electrode is formed.

In addition, the drain region 34 and the source region 33 of the transistor arrangement of the read region 30 are formed by implantation of a dopant of the N conductivity type. The first programming region is then connected by means of a metallic terminal PRG in an opening etched in the dielectric. At the same time, the second programming region 20 is connected by a metallic terminal CG, the body is connected by a metallic terminal B, the source is connected by a metallic terminal S, and the drain is connected by a metallic terminal BL in openings etched for this purpose.

In this context, the invention is not restricted to the exemplary embodiment shown in FIG. 1. Thus, for example, an N+ implantation can also be introduced in the active regions of the second programming region 20 that are not covered by polysilicon, in order to minimize the contact resistances. Additionally or alternatively, these surfaces are silicidized. In another example embodiment, two dopants of different conductivity types can be introduced on both sides of the tunneling region in the first programming region. For example, an N+ region and a P+ region can be formed by implantation. These regions make it possible for both an accumulation layer and an inversion channel to always be connected “equally well.” This would inherently provide a significant advantage for low temperatures or fast write processes.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A nonvolatile memory cell of a circuit integrated in a semiconductor chip comprising:
a read region;
a first programming region;
a second programming region;
a gate electrode; and
a dielectric insulator;
wherein the gate electrode is insulated from the read region, from the first programming region, and from the second programming region by the dielectric insulator,
wherein the gate electrode together with the dielectric insulator and the read region forms a transistor arrangement,
wherein the gate electrode together with the dielectric insulator and the first programming region forms a first capacitor,
wherein the gate electrode together with the dielectric insulator and the second programming region forms a second capacitor, and
wherein, with respect to a surface of the semiconductor chip, the gate electrode is located above the read region and above the first programming region and above the second programming region.

2. The nonvolatile memory cell according to claim 1, wherein the first programming region is insulated from the second programming region by the dielectric insulator.

3. The nonvolatile memory cell according to claim 1, wherein the first programming region and the second programming region are insulated from the read region by the dielectric insulator.

4. The nonvolatile memory cell according to claim 1, wherein the first programming region and/or the second programming region and/or the read region is arranged on a buried layer of the dielectric insulator and is insulated from a substrate of the semiconductor chip by the buried layer of the dielectric insulator.

5. The nonvolatile memory cell according to claim 1, wherein the first programming region and the second programming region and the read region are made from a single semiconductor layer and are insulated from one another by a trench structure filled with the dielectric insulator.

6. The nonvolatile memory cell according to claim 1, wherein the first programming region and/or the second programming region and/or the read region are electrically connected and are encapsulated by the dielectric insulator.

7. The nonvolatile memory cell according to claim 1, wherein the first programming region and the second programming region are made of monocrystalline semiconductor material.

8. The nonvolatile memory cell according to claim 1, wherein the first capacitor has a first capacitance and the second capacitor has a second capacitance, the first capacitance and the second capacitance being different.

9. The nonvolatile memory cell according to claim 8, wherein the first capacitor has a first capacitor area and the second capacitor has a second capacitor area, the first capacitor area and the second capacitor area being different.

10. The nonvolatile memory cell according to claim 8, wherein the dielectric insulator has a first thickness between the gate electrode and the first programming region and a second thickness between the gate electrode and the second programming region, and wherein the first thickness and the second thickness are different.

11. The nonvolatile memory cell according to claim 1, wherein the dielectric insulator has substantially the same thickness between the gate electrode and the first programming region and between the gate electrode and the second programming region.

12. A method for producing a nonvolatile memory cell in a semiconductor chip, the method comprising:
producing a gate electrode;
producing a read region, which together with the gate electrode forms a transistor arrangement;
producing a first programming region, which together with the gate electrode forms a first capacitor;
producing a second programming region, which together with the gate electrode forms a second capacitor;
producing a dielectric insulator, which insulates the gate electrode from the read region and from the first programming region and from the second programming region; and
depositing the gate electrode as a conductive layer on the dielectric insulator over the read region, over the first programming region, and over the second programming region.

13. The method according to claim 12, wherein the dielectric insulator is formed by substantially simultaneous thermal oxidation of semiconductor material of the read region, the first programming region, and the second programming region prior to the deposition of the gate electrode.

14. The method according to claim 12, wherein the first programming region with the gate electrode and the dielectric insulator is designed as a tunneling window, and wherein dopants with a first dopant concentration of one conductivity type are introduced into the first programming region independently of a dopant concentration of the same conductivity type in the read region.

15. Use of a nonvolatile memory cell according to any claim 1 in an integrated circuit with a number of integrated power transistors as an intelligent power circuit.
